(19) United States
(12) Patent Application Publication
(10) Pub. No.: US 2010/0315107 A1
(43) Pub. Date: Dec. 16, 2010

(54) ELECTRODE FOR ELECTROCHEMICAL MEASUREMENT APPARATUS AND ELECTRODE FOR BIOSENSORS

(75) Inventors: Toru Matsumoto, Tokyo (JP); Naoaki Sata, Tokyo (JP); Yoko Mitarai, Ibaraki (JP)

Correspondence Address: SUGHRUE MION, PLLC, 2100 PENNSYLVANIA AVENUE, N.W., SUITE 800, WASHINGTON, DC, 20037, US

(73) Assignees: NEC CORPORATION, Tokyo (JP); NATIONAL INSTITUTE FOR MATERIALS SCIENCE, Tsukuba-shi, Ibaraki (JP)

(21) Appl. No.: 12/867,726

(22) PCT Filed: Feb. 9, 2009
(86) PCT No.: PCT/JP2009/052453

§ 371 Date: Aug. 13, 2010

(30) Foreign Application Priority Data
Feb. 15, 2008 (JP) 2008-034075
Nov. 6, 2008 (JP) 2008-285762

(51) Int. Cl. G01R 27/08; H05K 13/00; H01J 1/02

(52) U.S. Cl. 324/693; 29/592.1; 313/311

(57) ABSTRACT

An object of this invention is to provide an inexpensive and highly durable electrode which is capable of causing hydrogen peroxide to generate a current output in the same manner as those of platinum or iridium. A working electrode (9) (electrode for electrochemical measurement apparatus (1)) for use in an electrochemical measurement apparatus 3 according to the invention is made of an alloy containing iridium and niobium, and the alloy has such a composition as to enable measurement of the concentration of hydrogen peroxide.

### BACKGROUND ART

This invention relates to an electrode for electrochemical measurement apparatus, an electrochemical measurement apparatus using an electrode for electrochemical measurement apparatus, an electrode for biosensors, a biosensor using an electrode for biosensors, a method of manufacturing an electrode for electrochemical measurement apparatus, a method of manufacturing an electrode for biosensors, a measuring method using an electrochemical measurement apparatus, and a measuring method using a biosensor.

For the purpose of analyzing components contained in a variety of solutions, widely used are methods of measuring an electrochemical reaction occurring on an electrode surface or measuring methods combining the electrochemical reaction with a catalytic reaction of a specific protein.

As an example of the former, concentration of hydrogen peroxide in a solution used as cleaning liquid or the like can be computed by measuring the oxidation current value of hydrogen peroxide obtained during application of a potential using a carbon electrode, or an electrode of a noble metal such as platinum.

This is because oxidation current according to the hydrogen peroxide concentration is generated during application of the potential.

As an example of the latter, a biosensor is widely used in which a chemical substance in a solution is converted into hydrogen peroxide by an enzyme's catalytic function, and this hydrogen peroxide is measured by an oxidation-reduction reaction.

More specifically, in the case of a glucose biosensor, gluconolactone and hydrogen peroxide are produced by oxidizing glucose with glucose oxidase.

Since the quantity of produced hydrogen peroxide is proportional to glucose concentration, the quantity of glucose in the specimen can be quantified by measuring the quantity of the produced hydrogen peroxide.

The quantity of the produced hydrogen peroxide is computed, as described above, by measuring the electrochemical reaction occurring on the electrode surface.

In such a type of electrodes, a noble metal is often used as a material having high oxidation capacity for hydrogen peroxide.

It is described in Japanese Laid-Open Patent Publication No. 2001-116716 (Patent Document 1), for example, that platinum is preferred as a material of an electrode shown in FIG. 1 of this patent document.

A working electrode shown in FIG. 2 of G Piechotta, J. Albers and R. Hintsche, “Novel Micromachined Silicon Sensor for Continuous Glucose Monitoring”, Biosensors and Bioelectronics, Volume 21, Issue 5, Elsevier B. V, (Netherlands), 15 Nov. 2005, p. 802-808 (Non-Patent Document 1) is made of platinum. Both of these electrodes are designed such that the quantity of glucose is measured by measuring the current value after application of a potential to hydrogen peroxide.

Further, an electrode material disclosed in Faming Tian and Guoyi Zhu, “Sol-gel derived iridium composite glucose biosensor”, Sensors and Actuators B: Chemical, Elsevier B. V, (Netherlands), Volume 86, September 2002, p. 266-270 (Non-Patent Document 2) is iridium oxide as.

On the other hand, except these noble metal electrodes, carbon electrodes as disclosed in Japanese Laid-Open Utility Model Publication No. H6-7057 (Patent Document 2) are also usable.

### DISCLOSURE OF THE INVENTION

Electrodes made of platinum as disclosed in Patent Document 1 or Non-Patent Document 1 are useful as electrodes for detecting hydrogen peroxide or electrochemical measurement apparatus or biosensors.

However, in the case of current sensing type hydrogen peroxide sensors manufactured by using platinum as an electrode material, there is a problem that these sensors become very expensive as platinum is a noble metal.

In the case of using iridium as an electrode material as disclosed in Non-Patent Document 2, further cost reduction is required although iridium is less expensive than platinum.

On the other hand, in the case of biosensors manufactured by using carbon as an electrode material as disclosed in Patent Document 2, there is a problem that the stability of the electrodes is so low that they cannot be used for a long period of time although the material cost is low.

This tendency is observed especially notably when carbon is used for enzyme electrodes, and it is extremely difficult for a biosensor manufactured by using carbon as an electrode material to stably maintain high measurement precision.

Furthermore, carbon electrodes, which are more apt to be damaged than those of a noble metal, have a problem that they require careful handling to prevent damages such as chipping of carbon.

This invention has been made in view of the reasons mentioned above, and it is an object of the invention to provide an electrode for electrochemical measurement apparatus, in which an alternative material is used in place of platinum, iridium, and carbon.

More specifically, it is an object of the invention to provide an inexpensive electrode for use in electrochemical measurement apparatus, which is capable of producing a current output for a specific component contained in a solution in the same manner as platinum and iridium, and is inexpensive and yet more durable than carbon. It is also an object of the invention to provide an electrochemical measurement apparatus manufactured using such an electrode, an electrode for biosensors using an electrode for electrochemical measurement apparatus, and a biosensor using an electrode for biosensors.

In order to achieve the objects described above, a first aspect of the invention provides an electrode for electrochemical measurement apparatus for detecting a specific component in a solution, the electrode containing at least iridium and niobium.

A second aspect of the invention provides an electrochemical measurement apparatus for measuring concentration of hydrogen peroxide in a solution, having the electrode for electrochemical measurement apparatus according to the first aspect of the invention.

A third aspect of the invention provides an electrode for biosensors for detecting a specific component in a solution, having an immobilized catalyst layer provided on the surface of the electrode for electrochemical measurement apparatus according to the first aspect of the invention.

A fourth aspect of the invention provides a biosensor for measuring concentration of a specific component in a solution, having the electrode for biosensors according to the third aspect of the invention.

A fifth aspect of the invention provides a method of manufacturing an electrode for electrochemical measurement apparatus for detecting a specific component in a solution, including the step of producing an alloy containing at least iridium and niobium by any of arc-melting method, an evaporation method, and a sputtering method.

A sixth aspect of the invention provides a method of manufacturing an electrode for biosensors for detecting a specific component in a solution, including the step of providing an immobilized catalyst layer on the surface of the electrode for electrochemical measurement apparatus according to the first aspect of the invention.

A seventh aspect of the invention provides a measurement method for measuring concentration of hydrogen peroxide in a solution by a current sensing method, using the electrochemical measurement apparatus according to the second aspect of the invention.

An eighth aspect of the invention provides a measurement method for measuring concentration of a specific component in a solution by a current sensing method, using the biosensor according to the fourth aspect of the invention.

### EFFECTS OF THE INVENTION

This invention is capable of providing an electrode for electrochemical measurement apparatus made of an alternative material in place of platinum, iridium, or carbon.

### BRIEF DESCRIPTION OF THE DRAWINGS

FIG. 1 is a schematic diagram showing an electrochemical measurement apparatus 3;

FIG. 2A is a schematic diagram showing a biosensor 3a;

FIG. 2B is a diagram showing a longitudinal-sectional view of the working electrode 9a (electrode for biosensors 4) of FIG. 2A;

FIG. 3 is a schematic diagram showing a biosensor 3b;

FIG. 4 is a cross-sectional view of the electrode for biosensors 4a of FIG. 3;

FIG. 5 is a diagram showing experimental results of Example 1;

FIG. 6 is a diagram showing experimental results of Example 2; and

FIG. 7 is a diagram showing experimental results of Example 4.

### LIST OF REFERENCE NUMERALS

1: Electrode for electrochemical measurement apparatus
3: Electrochemical measurement apparatus
3a: Biosensor
3b: Biosensor
4: Electrode for biosensors
5: Reference electrode
6: Immobilized catalyst layer (immobilized antibody layer)
7: Counter electrode
9: Working electrode
11: Wiring
13: Measuring device
15: Solution
23: Insulating substrate
24: Adhesion layer

### BEST MODE FOR CARRYING OUT THE INVENTION

Preferred embodiments of this invention will be described in detail with reference to the drawings.

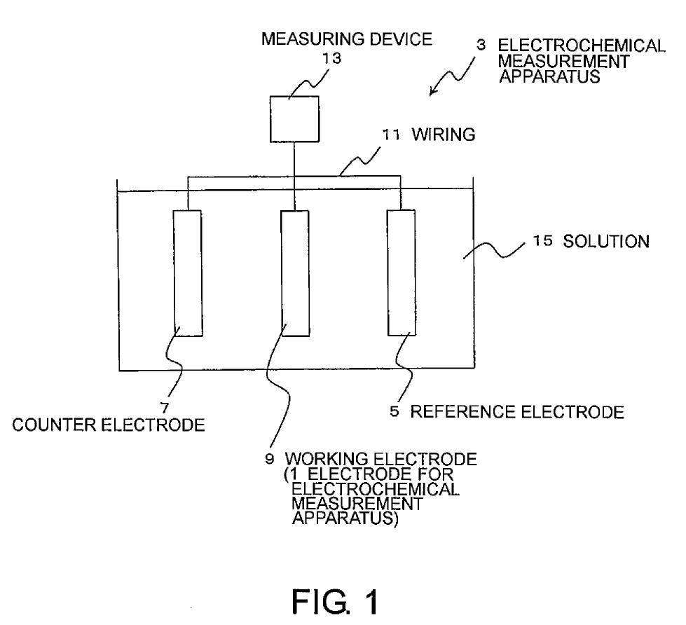

First, referring to FIG. 1, description will be made of configuration of an electrochemical measurement apparatus 3 having an electrode for electrochemical measurement apparatus 1 according to a first embodiment of this invention.

An electrochemical measurement apparatus for measuring concentration of hydrogen peroxide in a solution 15 is herein shown as an example of the electrochemical measurement apparatus 3.

The electrochemical measurement apparatus 3 shown in FIG. 1 has a working electrode 9 (electrode for electrochemical measurement apparatus 1) for oxidizing hydrogen peroxide in the solution 15, a reference electrode 5 which is an electrode serving as a potential reference, and a counter electrode 7 provided if necessary.

The electrochemical measurement apparatus 3 further has a measurement apparatus 13 for controlling application of potential during measurement, and for measuring concentration of hydrogen peroxide by measuring oxidation current, and wiring 11 for interconnecting the electrodes and the measurement apparatus 13.

The electrochemical measurement apparatus 3 is a device for measuring concentration of hydrogen peroxide in the solution 15 by immersing the working electrode 9, the counter electrode 7, and the reference electrode 5 in the solution 15 containing hydrogen peroxide, applying a constant potential by means of the measurement apparatus 13, and measuring the value of oxidation current obtained when the hydrogen peroxide is oxidized on the surface of the working electrode 9.

This means that the electrochemical measurement apparatus 3 measures the concentration of hydrogen peroxide in a solution by a current sensing method.

As described before, the working electrode 9 is desirably configured and made of a material such that it is capable of causing hydrogen peroxide to produce a current output in the same manner as platinum and iridium, and such that it is inexpensive and yet more durable than carbon.

As a result of earnest studies and researches done by the inventors of this invention in order to solve the above-mentioned problems, it has been found that an electrode which is less expensive than electrodes made of platinum or iridium alone and more durable than those made of carbon can be obtained by employing an alloy containing at least iridium and niobium in such proportions that it is possible to cause hydrogen peroxide to produce a current output.

The materials in the alloy will be described in more detailed manner.

Iridium has strong oxidizability to oxidize hydrogen peroxide and is a material which is less expensive and yet superior in processability in comparison with platinum conventionally used as a material of working electrodes. Furthermore, being more durable than carbon, iridium is indispensable to oxidize hydrogen peroxide in the solution 15.

Niobium has barely oxidizability to oxidize hydrogen peroxide and is an element which is less expensive than platinum or iridium, more durable than carbon, and hence is indispensable.

The content of niobium in the alloy is desirably from 10 to 50 atomic percent, and more desirably from 11 to 24 atomic percent with respect to the content of iridium in the alloy.

Alternatively, the atomic ratio of iridium to niobium in the alloy is desirably in the range of 90:10 to 50:50, and more desirably in the range of 89:11 to 76:24.

If the composition is out of the range described above, sufficient selectivity to hydrogen peroxide cannot be obtained, possibly inducing a problem of a narrowed potential window.

It is believed this is because the oxidation nature and potential window are affected by the ratio of iridium to niobium.

The alloy may be composed only of iridium and niobium.

The above-described alloy may be produced for example by an arc-melting method, an evaporation method, or a sputtering method. The arc-melting method is preferable in terms of the fact that the alloy can be produced without waste of the raw materials.

The reference electrode 5 may be a known electrode such as a glass composite electrode, for example.

The counter electrode 7 also may be a known electrode such as a platinum electrode, for example.

A method of measuring concentration of hydrogen peroxide in the solution 15 with the use of the electrochemical measurement apparatus 3 will be described in detail.

First, the working electrode 9, the counter electrode 7, and the reference electrode 5 are immersed in the solution 15 containing hydrogen peroxide.

The solution 15 is for example a cleaning liquid used in manufacture of food products.

Once the electrodes are immersed in the solution 15, a constant potential is applied with the use of the measurement apparatus 13.

The application of the potential oxidizes the hydrogen peroxide on the surface of the working electrode 9, whereby oxidation current is generated.

The measurement apparatus 13 measures the oxidation current, and measures the concentration of hydrogen peroxide in the solution 15 based on the measured value of the oxidation current.

According to the first embodiment, as described above, the electrochemical measurement apparatus 3 has the working electrode 9, the counter electrode 7, the reference electrode 5, and the measurement apparatus 13, the working electrode 9 being formed of an alloy containing iridium and niobium in such proportions that it is possible to cause hydrogen peroxide to generate a current output.

Therefore, the working electrode 9 is less expensive than those formed of platinum or iridium alone and more durable than those formed of carbon. Thus, the working electrode 9 can be used as an alternative to a platinum, iridium, or carbon electrode.

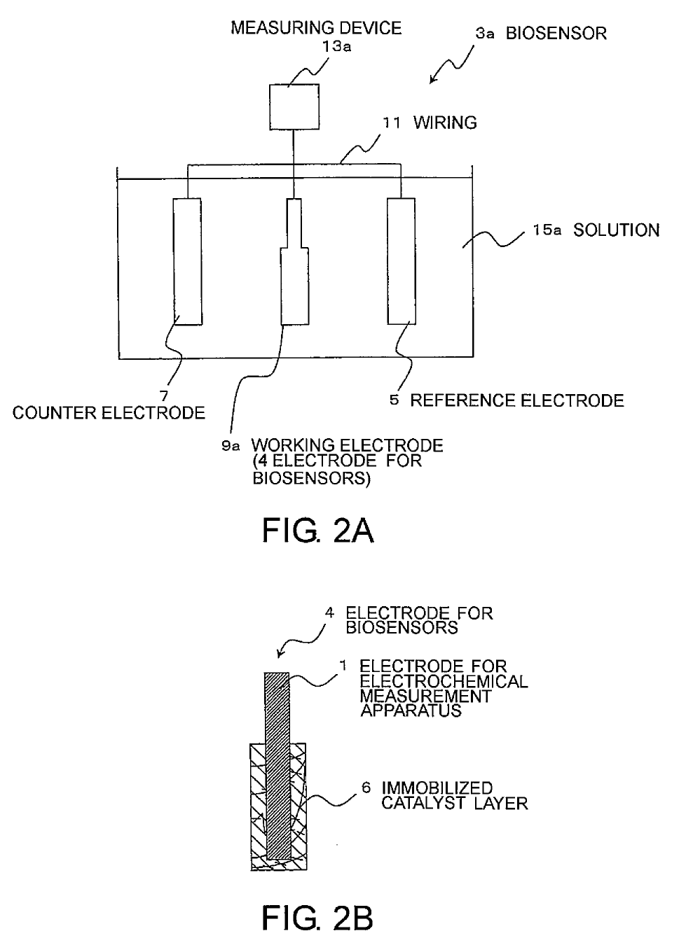

A second embodiment will be described with reference to FIG. 2.

The second embodiment differs from the first embodiment in that the working electrode 9a is replaced with an electrode for biosensors 4 the surface of which is covered with an immobilized catalyst layer 6, and the device as a whole is formed as a biosensor 3a.

In the following description of the second embodiment, elements having the same effects as those of the first embodiment are assigned with the same reference numerals and description thereof will be omitted.

As shown in FIG. 2A, configuration of the biosensor 3a is the same as that of the electrochemical measurement apparatus 3, except that the biosensor 3a has a working electrode 9a (electrode for biosensors 4) the surface of which is covered with an immobilized catalyst layer 6.

Further, the biosensor 3a has a measurement apparatus 13a for controlling the application of potential during measurement, measuring the oxidation current, and measuring the concentration of the substance to be measured.

As shown in FIG. 2B, the electrode for biosensors 4 has an electrode for electrochemical measurement apparatus 1, and an immobilized catalyst layer 6 provided on the surface of the electrode for electrochemical measurement apparatus 1.

Configuration and composition of this electrode for electrochemical measurement apparatus 1 are the same as those of the electrode for electrochemical measurement apparatus 1 of the first embodiment, and an alloy is used therein, which contains iridium and niobium and has such a composition that it is possible to cause hydrogen peroxide to generate a current output.

The immobilized catalyst layer 6 may be, for example, an immobilized enzyme layer or an immobilized antibody layer.

An immobilized enzyme layer is a layer containing an enzyme for converting the substance to be measured into hydrogen peroxide.

When the immobilized catalyst layer 6 is an immobilized enzyme layer, the biosensor 3a is capable of measuring the concentration of the substance to be measured in the solution 15a, by the enzyme in the immobilized catalyst layer 6 converting the substance to be measured into hydrogen peroxide, and by measuring the oxidation current generated when the hydrogen peroxide thus obtained is oxidized on the surface of the electrode for electrochemical measurement apparatus 1.

This means that the biosensor 3a is capable of measuring the concentration of the substance to be measured in the solution by measuring the concentration of hydrogen peroxide by means of a current sensing method.

The enzyme used for this purpose must be an enzyme which produces hydrogen peroxide as a product of the catalytic reaction of the substance to be measured, or consumes oxygen, and the enzyme may be selected, according to the substance to be measured, from among lactate oxidase, glucose oxidase, urate oxidase, urea oxidase, alcohol oxidase, and so on.

Two or more types of enzymes may be used simultaneously. Such enzymes are exemplified by creatininase, creatinase, and sarcosine oxidase.

The use of these enzymes makes it possible to detect creatinine.

Additionally, an enzyme and a coenzyme may be used together.

As the method of immobilizing the enzyme on the surface of the electrode for electrochemical measurement apparatus 1, a well-known method, such as a method utilizing cross-linking reaction, can be used.

More specifically, an enzyme solution, a cross-linking agent for a protein such as glutaraldehyde, and a solution containing a protein such as albumin are put in drops on the surface of the electrode for electrochemical measurement apparatus 1, whereby the enzyme is immobilized and an immobilized enzyme layer is formed as the immobilized catalyst layer 6 on the surface of the electrode for electrochemical measurement apparatus 1.

In contrast, when the immobilized catalyst layer 6 is an immobilized antibody layer, electrons are exchanged during reaction between the antibody and antigen in the solution. Therefore, the biosensor 3a is capable of measuring the current generated due to the exchange of electrons by performing square-wave voltammetry, for example, and thus is capable of measuring the concentration of a specific substance in the solution.

The antibody may be selected, according to the substance to be measured, from among antibodies against dioxin, antibodies against endocrine disruptors, antibodies against residual pesticides, and so on.

The immobilization of the antibody may be implemented by a method in which a carboxyl group is introduced onto the surface of the electrode for electrochemical measurement apparatus 1, and the antibody is immobilized after treatment with an amino coupling agent to form an immobilized antibody layer.

Configuration of the immobilized catalyst layer 6 is not limited specifically so far as it contains an enzyme, it has a function to convert the substance to be measured to hydrogen peroxide, or it contains an antibody, and so far as it is configured such that exchange of electrons is caused at a specific applied potential and a current value is generated as an output.

A method of measuring concentration of a substance to be measured solution 15a with the use of the biosensor 3a will be described in detail.

First, the working electrode 9a, the counter electrode 7, and the reference electrode 5 are immersed in the solution 15a containing a substance to be measured.

When the immobilized catalyst layer 6 is an immobilized enzyme layer, a constant potential is applied by means of the measurement apparatus 13a once the electrodes are immersed in the solution 15a.

Once the electrodes are immersed in the solution 15a, the substance to be measured in the solution 15a comes into contact with the immobilized enzyme layer on the working electrode 9a, and converted into hydrogen peroxide by catalytic reaction. The hydrogen peroxide thus obtained is oxidized by application of a potential on the surface of the electrode for electrochemical measurement apparatus 1 of the working electrode 9a, whereby oxidation current is generated.

The measurement apparatus 13a measures the oxidation current, and measures the concentration of the hydrogen peroxide based on the measured oxidation current.

Further, the measurement apparatus 13a measures the concentration of the substance to be measured in the solution 15a based on the measured hydrogen peroxide concentration.

When the immobilized catalyst layer 2 is an immobilized antibody layer, the antibody reacts with the substance to be measured once the electrodes are immersed in the solution 15a. Thus, the current value obtained by the reaction is measured by a square wave voltammetry method by means of the measurement apparatus 13a, and the concentration of the substance to be measured in the solution 15a is determined based on the current value.

According to the second embodiment, as described above, the biosensor 3a has the working electrode 9a, the counter electrode 7, the reference electrode 5, and the measurement apparatus 13a. The electrode for electrochemical measurement apparatus 1 of the working electrode 9a is formed of an alloy containing iridium and niobium, and the alloy has such a composition that it is possible to cause hydrogen peroxide to generate a current output.

Accordingly, the second embodiment provides the same advantageous effects as those of the first embodiment.

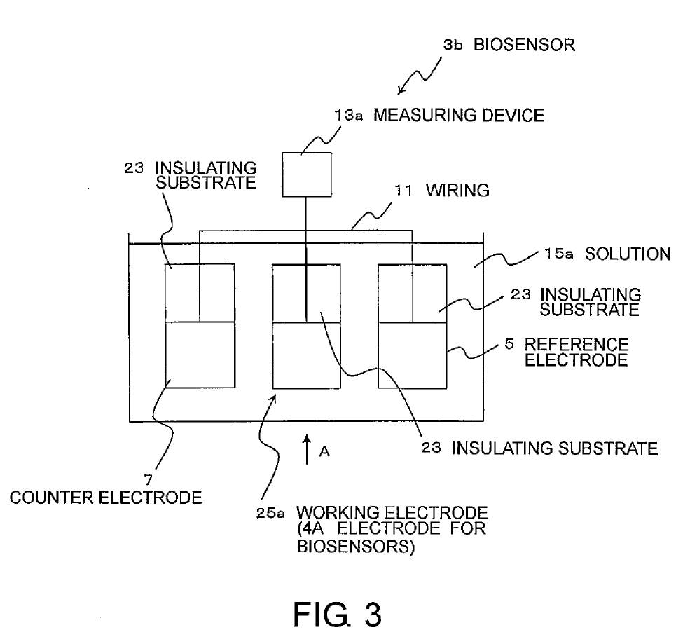

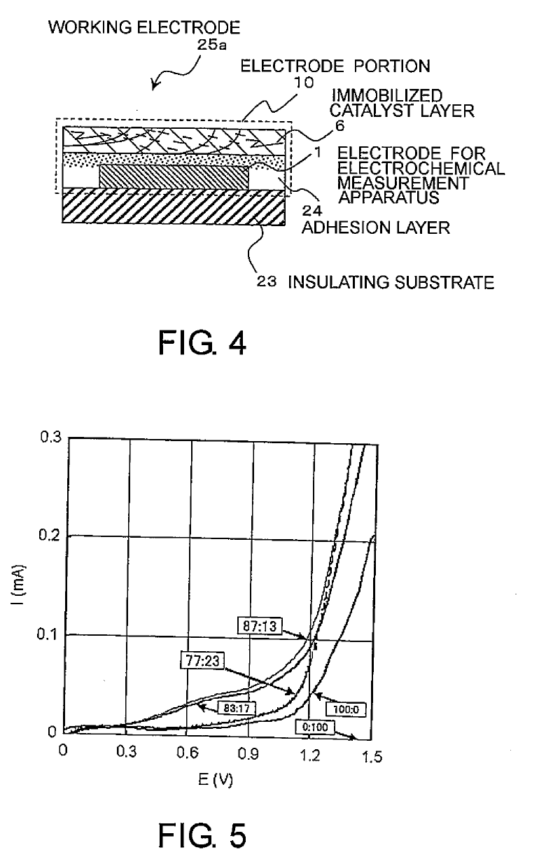

A third embodiment will be described with reference to FIG. 3 and FIG. 4.

A biosensor 3b according to the third embodiment differs from the second embodiment in that the electrode for electrochemical measurement apparatus 1 is provided on an insulating substrate 23 and an adhesion layer 24 is further provided between the electrode for electrochemical measurement apparatus 1 and an immobilized catalyst layer 6 to form a working electrode 25a (electrode for biosensors 4a).

As shown in FIG. 3 and FIG. 4, the working electrode 25a (electrode for biosensors 4a) has an insulating substrate 23, and an electrode for electrochemical measurement apparatus 1 provided on the surface of the insulating substrate 23.

As shown in FIG. 4, the working electrode 25a (electrode for biosensors 4a) also has an immobilized catalyst layer 6 provided above the electrode for electrochemical measurement apparatus 1 as viewed in FIG. 4.

Further, the working electrode 25a has an adhesion layer 24 provided between the electrode for electrochemical measurement apparatus 1 and the immobilized catalyst layer 6, and provided on the insulating substrate 23 and electrode for electrochemical measurement apparatus 1 so as to cover the electrode for electrochemical measurement apparatus 1.

The immobilized catalyst layer 6 is provided on the adhesion layer 24.

The electrode for electrochemical measurement apparatus 1, the immobilized catalyst layer 6, and the adhesion layer 24 together form an electrode portion 10.

The insulating substrate 23 is a member for holding the electrode portion 10, and is preferably made of a material having good water resistance, heat resistance, chemical resistance, and insulating quality, and having high adhesion properties with the electrode for electrochemical measurement apparatus 1.

Materials satisfying these requirements include ceramics, glass, quartz, and plastics, for example.

The adhesion layer 24 is provided for the purpose of improving the adhesion properties (bonding properties) of the immobilized catalyst layer 6 with the insulating substrate 23 and electrode for electrochemical measurement apparatus 1.

The adhesion layer 24 also has an advantageous effect of improving the wettability of the surface of the insulating substrate 23 and improving the uniformity of the thickness of the film when the immobilized catalyst layer 6 is formed.

The adhesion layer 24 may be formed of a silane coupling agent, for example.

The silane coupling agents usable for this purpose include aminosilane, vinylsilane, and epoxysilane, whereas a type of aminosilane, namely y-aminopropyltriethoxysilane is more preferable in view of adhesion properties.

The adhesion layer 24 can be formed on the insulating substrate 23 and electrode for electrochemical measurement apparatus 1, for example, by spin-coating the silane coupling agent solution.

Preferably, the concentration of the silane coupling agent is about 1 v/v % (volume/volume %). This concentration of the silane coupling agent ensures sufficient hydration of the alkoxyl group and sufficient adhesion properties.

Although in FIG. 4, there is provided a single electrode portion 10 on a single insulating substrate 23, a plurality of electrode portions 10 may be provided on a single insulating substrate 23.

Although in FIG. 3, the counter electrode 7 and the reference electrode 5 are formed on separate insulating substrates 23, all the electrodes may be formed on a single insulating substrate 23.

A method of manufacturing the working electrode 25a will be briefly described. First, the electrode for electrochemical measurement apparatus 1 is provided on the insulating substrate 23 by using an evaporation method, a sputtering method or the like.

Then, the adhesion layer 24 is provided on the insulating substrate 23 and electrode for electrochemical measurement apparatus 1 by spin-coating so as to cover the electrode for electrochemical measurement apparatus 1.

Then, an enzyme solution, a solution containing a protein cross-linking agent such as glutaraldehyde, and albumin are put in drops on the adhesion layer 24, whereby an immobilized enzyme layer is formed as the immobilized catalyst layer 6 and the working electrode 25a is completed.

The method of measuring the concentration of the substance to be measured in the solution 15a with the use of the biosensor 3b is the same as in the second embodiment, and therefore description thereof will be omitted.

According to the third embodiment, as described above, the biosensor 3b has the working electrode 25a, the counter electrode 7, the reference electrode 5, and the measurement apparatus 13a. The electrode for electrochemical measurement apparatus 1 of the working electrode 25a is formed of an alloy containing iridium and niobium and the alloy has such a composition that it is possible to cause hydrogen peroxide to generate a current output.

Accordingly, the third embodiment provides the same advantageous effects as those of the second embodiment.

Further, according to the third embodiment, the working electrode 25a has a configuration in which the electrode for electrochemical measurement apparatus 1 is provided on the insulating substrate 23, and the adhesion layer 24 is further provided between the electrode for electrochemical measurement apparatus 1 and the immobilized catalyst layer 6.

In comparison with the second embodiment, the third embodiment therefore improves the adhesion properties (bonding properties) between the immobilized catalyst layer 6 and the electrode for electrochemical measurement apparatus 1, and improves more the uniformity of film thickness when the immobilized catalyst layer 6 is formed.

### EXAMPLES

This invention will be described in more detail based on specific examples.

### Example 1

The electrochemical measurement apparatus 3 shown in FIG. 1 was fabricated using an electrode of iridium-niobium alloy, cyclic voltammetry measurement was conducted on indicating electrolyte solution, and the obtained result was compared with the case in which an electrode formed of iridium or niobium alone was used.

First, the working electrode 9 (electrode for electrochemical measurement apparatus 1) was fabricated in the following manner.

First, iridium wire and niobium wire (both manufactured by Furuuchi Chemical Corporation) were prepared, and specimens of iridium-niobium alloy, of iridium alone, and of niobium alone were produced by arc discharge.

More specifically, five different specimens having atomic ratios of iridium to niobium of 100:0, 87:13, 83:17, 77:23, and 0:100, respectively, were produced.

Each of the specimens thus produced was fixed to a flexible substrate having printed wiring thereon with the use of an adhesive agent, electrically connected by wire bonding, and then water-proofed with a silicone sealing agent manufactured by Shin-Etsu Chemical Co., Ltd., to form a working electrode 9 (electrode for electrochemical measurement apparatus 1).

The electrode area of the working electrode 9 was 36 to 39×10⁻⁶ m².

Then, an existing glass composite electrode (GST-5741C, manufactured by DKK To a Corporation) was prepared as the reference electrode 5, and an existing platinum electrode (002233, manufactured by BAS Inc.) was prepared as the counter electrode 7.

Then, an indicating electrolyte solution (100 mM (100 mol/m³) of N-tris (hydroxy-methyl)-methyl-2-aminoethanesulphonic acid (pH buffer manufactured by Dojindo Laboratories, with pH adjusted to 7, and containing 150 mM (150 mol/m³) sodium chloride (manufactured by Wako Pure Chemical Industries)) was prepared as the solution 15. The working electrode 9, the reference electrode 5, and the counter electrode 7 were immersed in the solution 15, and these electrodes were connected to the measurement apparatus 13 (CompactStat manufactured by Ivium Technologies) through the wiring 11, whereby the electrochemical measurement apparatus 3 was fabricated.

The measurement was performed by cyclic voltammetry on the indicating electrolyte solution.

The measurement was performed under the condition of sweeping the range of −1.5 V to +1.5 V once at 0.01 V/s.

FIG. 5 shows the results of current values obtained by sweeping the range of 0 to 1.5V.

As seen from FIG. 5, it was found that a potential window close to the atomic ratio of iridium to niobium of 100:0 (electrode formed of iridium alone) could be obtained when the atomic ratio was 77:23, and they were substantially the same near the range of 0.6 to 0.7 V.

It is believed this is because water electrolysis capability, that is, catalytic power of decomposing water is minimized at this atomic ratio.

The results described above revealed that since the content iridium can be reduced while adding less expensive niobium by that much, it is possible to provide an electrode at a lower cost which is capable of detecting hydrogen peroxide (capable of causing hydrogen peroxide to generate a current output).

### Example 2

Electrodes with atomic ratios of iridium to niobium of 100:0, 77:23 and 0:100, respectively, were fabricated in the same mariner as in Example 1, and each of the electrodes was subjected to experiments as the working electrode 9.

Subsequently, constant-potential measurement was conducted on the indicating electrolyte of Example 1 having a final concentration of 2.47 mM (2.47 mol/m³) hydrogen peroxide (manufactured by Kanto Chemical Co., Ltd.) and 10 mM (10 mol/m³) ascorbic acid (manufactured by Wako Pure Chemical Industries). The measurement was conducted by immersing the working electrode 9 in the above-mentioned indicating electrolyte, applying 0.7 V potential, and letting it stand until a steady state was reached (for about five minutes).

After that, hydrogen peroxide and ascorbic acid were added so that the respective final concentrations were obtained.

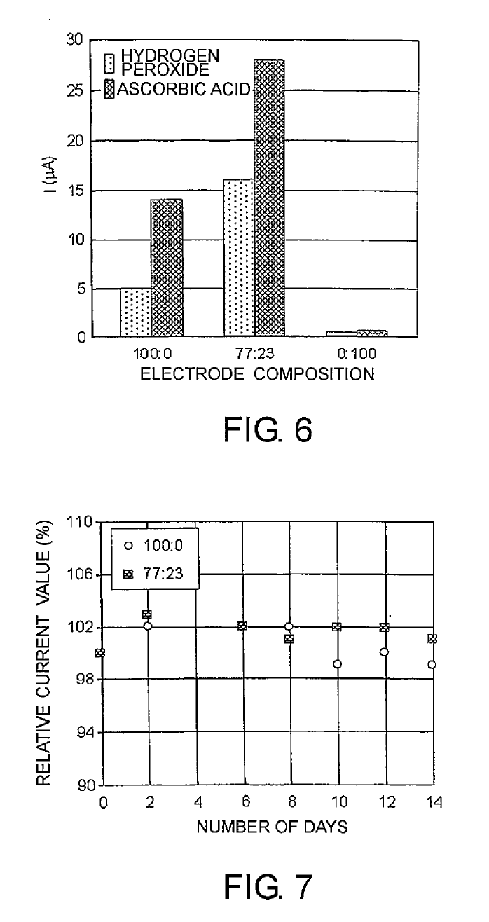

Response current values were each obtained as a difference between a current value in the steady state and a current value obtained from hydrogen peroxide and ascorbic acid. The results are shown in FIG. 6.

In the graph of FIG. 6, miroampere response current values are plotted along the vertical axis, and compositions of the working electrode 9 are shown in the horizontal axis.

The results revealed that the working electrode 9 of an iridium-niobium alloy of this Example reacts with hydrogen peroxide and ascorbic acid in the same manner as the one made of iridium alone, and improves the reaction efficiency further than the one made of iridium alone.

This means that it was found that the addition of niobium increases the response current values of hydrogen peroxide and ascorbic acid.

On the other hand it was found that the electrodes made of 100% iridium or 100% niobium are inferior in detection sensitivity for hydrogen peroxide.

The results described above revealed an alloy of iridium and niobium is advantageously usable as an electrode for an amperometric biosensor.

### Example 3

Among the electrodes used in Example 2, two different types of electrodes with respective atomic ratios of iridium to niobium of 100:0 and 77:23 were prepared and subjected to electrochemical cleaning in 0.1M (0.1×10³ mol/m³) sodium sulfate solution.

The cleaning was performed under the condition of sweeping the range of −1.5 V to +1.5 V a hundred times at 0.01 V/s.

Subsequently, gamma-aminopropyltriethoxysilane (manufactured by Shin-Etsu Chemical Co., Ltd.) diluted to 1 v/v % with pure water was spin-coated on the surface of each of the electrodes and dried at 110° C.

Subsequently, a bovine albumin solution (manufactured by Wako Pure Chemical Industries) adjusted with the aforementioned indicating electrolyte solution, a glutaraldehyde solution (manufactured by Aldrich Corporation) adjusted to 0.5 v/v % with pure water, and glucose oxidase adjusted to 376.7 U/μl were mixed, and the mixture was immediately spin-coated in the same manner to fabricate a glucose enzyme sensor (electrode for biosensors).

Subsequently, constant potential measurement was conducted on glucose (manufactured by Wako Pure Chemical Industries) with a final concentration of 0.1×10⁻³ kg/l.

The measurement was conducted by immersing the aforementioned electrodes (the reference electrode and the counter electrode) and the electrode for biosensors in the indicating electrolyte, applying 0.7 V potential, and then letting them stand until a steady state is reached (for about five minutes).

After that, glucose solution was added so that the aforementioned concentration was obtained as the final concentration.

Difference between a current value obtained after addition of glucose and a current value in the steady state was obtained.

The applied potential was 0.7 V.

The measurement described above was repeated ten times, and values of repeatability were computed using the following equation and compared.

Value of repeatability (%)=(standard deviation of current value/average value of current values)×100 (Eq.)

As a result, it was found that the repeatability was 3.1% for the electrode for biosensors in which the 100:0 electrode was used, 2.9% for the electrode for biosensors in which the 77:23 electrode was used, and hence the addition of niobium did not cause deterioration of sensor characteristics.

### Example 4

Firstly, electrodes for biosensors as described in Example 3 were fabricated.

Subsequently, the electrodes for biosensors were stored in the aforementioned indicating electrolyte solution, and the response current to 0.1 kg/1 glucose was measured at regular time intervals to evaluate its long-term working life.

The measurement conditions were the same as in Example 3.

The evaluation was performed by a method in which the aforementioned measurement was conducted every day, and the measurement was continued every two days for 14 days.

The results are shown in FIG. 7.

In FIG. 7, the white circles indicate the current values of the electrode for biosensors fabricated with an electrode formed of iridium alone, and the stippled squares indicate the current values of the electrode for biosensors fabricated with an electrode containing iridium and niobium in the atomic ratio of 77:23, the current values being represented in relative current values to the first-day current value represented as 100%.

As seen from FIG. 7, the results revealed that both the electrode for biosensors using the 100:0 electrode and the electrode for biosensors using the 77:23 electrode did not show significant variation in current value, and the current values were very stable.

Therefore, it was found that the addition of iridium and niobium as electrode materials does not affect the long-term working life.

### Example 5

An electrode for biosensors for detecting an endocrine disruptor was fabricated and the response current to the endocrine disruptor was measured.

Firstly, an electrode with an atomic ratio of iridium to niobium of 77:23 was fabricated by an arc discharge method and mounted on a glass substrate.

This was electrically connected to an electrode substrate, and sealed with a silicone sealing material.

The electrode area was 5.5×10⁻⁶ m² (5.5 mm²)

Subsequently, electrochemical cleaning was performed in 0.1 M (0.1×10³ mol/m³) sodium sulfate solution.

The cleaning was performed under the condition of sweeping the range of −1.5 V to +1.5 V a hundred times at 0.5 V/s.

Subsequently, MUA (11-mercaptoundecylic acid) was solved in a small amount of ethanol as thiol molecules for a self-assembly monomolecular membrane, and adjusted with distilled water to give a final concentration of 1 mM (1 mol/m³).

One ml of this solution was put in drops on the surface of the electrode, let stand for about one hour, and then cleaned with ethanol.

Subsequently, bisphenol A monoclonal antibody (manufactured by Cosmo Bio Co., Ltd.) as one of internal disrupters was prepared in 200×10⁻⁶ kg/l (200 microgram/ml, containing pH—7.4 and 10 mM (10 mol/m³) phosphate buffer, 0.2% fetal bovine serum albumin, and 0.09% sodium azide), dispensed in 40×10⁻⁶ liter (40 microliter) volumes, and put in drops on the surface of the electrode.

This was dried at room temperature for one hour, then immersed in 1 w/v % polyvinyl alcohol for one hour, and further dried at room temperature for one hour.

Using this electrode as a working electrode, the response current to bisphenol A in the solution was measured by the square wave voltammetry method with the use of a glass reference electrode and a platinum counter electrode.

The measurement was performed under the conditions that the sweeping range was 0.1 to 1.2 V, the pulse potential was 40×10⁻³ V (40 mV), the frequency was 4 Hz, and the step potential was 10×10⁻³ V (10 mV).

As a result, it was confirmed that a response current in the order of microamperes was obtained to 1 ppb bisphenol A.

It has been found that, according to this invention as described above, an electrode of an iridium-niobium alloy can be applied as a substitute for a platinum electrode (or a carbon electrode).

It has been also found that when an electrode for biosensors is fabricated using this electrode, a biosensor can be provided which is capable of measuring in the same manner as a platinum electrode (or a carbon electrode).

Although the description of the embodiments and examples above has been made in terms of a case in which an electrode containing iridium and niobium is applied in the electrochemical measurement apparatus 3 for measuring hydrogen peroxide concentration, this invention is not limited to this in any way. The invention is applicable to measurement apparatus for measuring concentration of any other substances having selective oxidizability to an electrode containing iridium and niobium.

This application is based upon and claims the benefit of priority from Japanese Patent Application No. 2008-034075, filed Feb. 15, 2008, and Japanese Patent Application No. 2008-285762, filed Nov. 6, 2008, the disclosure of both of which is incorporated herein in their entirety by reference.

1-24. (canceled)

25. An electrode for electrochemical measurement apparatus for detecting a specific component contained in a solution, wherein the electrode is made of an alloy containing iridium and niobium in proportions that it is possible to cause hydrogen peroxide to generate a current output.

26. The electrode for electrochemical measurement apparatus as claimed in claim 25, wherein the alloy is an iridium-niobium alloy.

27. A detection device for detecting hydrogen peroxide in a solution comprising an electrode for electrochemical measurement apparatus which is made of an alloy comprising iridium and niobium in such proportions that it is possible to cause hydrogen peroxide to generate a current output.

28. An electrode for biosensors for detecting a substance to be measured in a solution, comprising an immobilized catalyst layer provided on the surface of the electrode for electrochemical measurement apparatus as claimed in claim 25.

29. The electrode for biosensors as claimed in claim 28, wherein:
the immobilized catalyst layer is an immobilized enzyme layer;
the immobilized enzyme layer has at least one type of enzyme which is capable of converting the specific component into hydrogen peroxide; and
the specific component is detected by the electrode for electrochemical measurement apparatus detecting the hydrogen peroxide obtained by the conversion by the immobilized enzyme layer.

30. The electrode for biosensors as claimed in claim 29, wherein the enzyme is at least one selected from lactate oxidase, glucose oxidase, urate oxidase, urea oxidase, alcohol oxidase, creatininase, creatinase, and sarcosine oxidase.

31. The electrode for biosensors as claimed in claim 28, wherein:
the immobilized catalyst layer is an immobilized antibody layer;
the immobilized antibody layer has at least one type of antibody capable of reacting with the specific component; and
the specific component is detected by the electrode for electrochemical measurement apparatus detecting a current generated by the reaction between the antibody in the immobilized antibody layer and the specific component.

32. The electrode for biosensors as claimed in claim 31, wherein the antibody is any one selected from antibodies against dioxins, antibodies against endocrine disruptors, and antibodies against residual pesticides.

33. The electrode for biosensors as claimed in claim 28, further comprising:
an insulating substrate for holding the electrode for electrochemical measurement apparatus; and
an adhesion layer provided between the electrode for electrochemical measurement apparatus and the immobilized catalyst layer, and provided on the insulating substrate and the electrode for electrochemical measurement apparatus so as to cover the electrode for electrochemical measurement apparatus.

34. A biosensor for measuring concentration of a substance to be measured in a solution, comprising the electrode for biosensors as claimed in claim 28.

35. A method of manufacturing an electrode for electrochemical measurement apparatus for detecting a specific component in a solution, comprising; producing an alloy containing iridium and niobium in such proportions that it is possible to cause hydrogen peroxide to generate a current output, by any of an arc-melting method, an evaporation method, and a sputtering method.

36. A method of manufacturing an electrode for biosensors for detecting a specific component in a solution, comprising; providing an immobilized catalyst layer on the surface of the electrode for electrochemical measurement apparatus as claimed in claim 25.

37. The method of manufacturing an electrode for biosensors as claimed in claim 36, wherein said providing is a providing an immobilized enzyme layer as the immobilized catalyst layer by immobilizing an at least one type of enzyme capable of converting the specific component into hydrogen peroxide, on the surface of the electrode for electrochemical measurement apparatus.

38. The method of manufacturing an electrode for biosensors as claimed in claim 37, wherein said providing is a providing the immobilized enzyme layer by immobilizing at least one of lactate oxidase, glucose oxidase, urate oxidase, urea oxidase, alcohol oxidase, creatininase, creatinase, and sarcosine oxidase, on the surface of the electrode for electrochemical measurement apparatus.

39. The method of manufacturing an electrode for biosensors as claimed in claim 36, wherein said providing is a providing an immobilized antibody layer as the immobilized catalyst layer by immobilizing at least one type of antibody capable reacting with the specific component, on the surface of the electrode for electrochemical measurement apparatus.

40. The method of manufacturing an electrode for biosensors as claimed in claim 39, wherein said providing is a providing the immobilized antibody layer by immobilizing any one of antibodies against dioxins, antibodies against endocrine disruptors, and antibodies against residual pesticides on the surface of the electrode for electrochemical measurement apparatus.

41. A detection method of detecting hydrogen peroxide in a solution by a current sensing method, using an electrode for electrochemical measurement apparatus which is made of an alloy containing iridium and niobium in such proportions that it is possible to cause hydrogen peroxide to generate a current output.

42. A detection method of detecting concentration of a specific component in a solution by a current sensing method, using the biosensor as claimed in claim 34.

43. The detection device as claimed in claim 27, wherein the alloy is an iridium-niobium alloy.

44. The detection method as claimed in claim 41, wherein the alloy is an iridium-niobium alloy.
